(19) United States
(12) Patent Application Publication
(10) Pub. No.: US 2011/0260245 A1
(43) Pub. Date: Oct. 27, 2011

(54) Cost Effective Global Isolation and Power Dissipation For Power Integrated Circuit Device

(75) Inventors: Ruey-Hsin LIU, Hsin-Chu (TW); Puo-Yu CHIANG, Su-ao Township (TW); Chih-Wen YAO, Hsinchu City (TW); Yu-Chang JONG, Hsinchu City (TW); Hsiao-Chin TUAN, juDong County (TW)

(73) Assignee: TAIWAN SEMICONDUCTOR MANUFACTURING COMPANY, LTD., Hsin-Chu (TW)

(21) Appl. No.: 12/766,454

(22) Filed: Apr. 23, 2010

(51) Int. Cl. H01L 29/78; H01L 21/762

(52) U.S. Cl. 257/337; 438/424; 257/E29.261; 257/E21.546

(57) ABSTRACT

An integrated circuit device and method for fabricating the integrated circuit device is disclosed. In an embodiment, an apparatus includes a substrate having a first surface and a second surface, the second surface being opposite the first surface; a first device and a second device overlying the substrate; and an isolation structure that extends through the substrate from the first surface to the second surface and between the first device and the second device.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed.

The capability of integrating analog, digital, and high power (high voltage and high current) functionality in a single technology has been important in the design of various electronic systems. As high power devices are integrated into single technology devices, isolation and power dissipation of such devices becomes a concern. Current techniques for isolating high power devices, such as lateral double-diffused metal-oxide-semiconductor (LDMOS) devices, include junction isolation and silicon-on-insulator (SOI) isolation. The junction isolation technique uses doped wells or oxide features that extend along the sides of the devices and only partially through the semiconductor substrate, for example partially through the substrate to a buried layer. The SOI isolation technique similarly uses oxide features that extend along the sides of the devices and only partially through the semiconductor substrate, for example partially through the substrate to a buried oxide layer disposed within the substrate. Although these approaches have been satisfactory for their intended purposes, they have not been entirely satisfactory in all respects.

### SUMMARY

The present disclosure provides for many different embodiments. According to one of the broader forms of the invention, an apparatus includes a substrate having a first surface and a second surface, the second surface being opposite the first surface; a first device and a second device overlying the substrate; and an isolation structure that extends through the substrate from the first surface to the second surface and between the first and second devices. The isolation structure may extend laterally along the sides of each device. The first and/or second device may be a lateral double-diffused metal-oxide-semiconductor (LDMOS) device.

According to another of the broader forms of the invention, an integrated circuit device includes a semiconductor substrate having a first surface and a second surface, the second surface being opposite the first surface; and a device that includes a source and drain region having a first type of conductivity disposed in the substrate, a gate structure disposed over the first surface of the substrate and between the source and drain region, and a body contact region having a second type of conductivity disposed in the substrate and adjacent to the source region, the second type of conductivity being different than the first type of conductivity. The integrated circuit device further includes an isolation structure disposed in the semiconductor substrate between the device and a neighboring device, the isolation structure extending through the substrate from the first surface to the second surface.

According to another of the broader forms of the invention, a method includes providing a substrate having a first surface and a second surface, the first surface being opposite the second surface, and forming an isolation structure that extends partially through the substrate from the first surface. The isolation structure is formed surrounding an active region of the substrate. An integrated circuit device is formed in the active region of the substrate. The method further includes bonding a carrier wafer to the first surface of the substrate, and polishing the second surface of the substrate until the isolation structure is reached, such that the isolation structure extends entirely through the substrate from the first surface to the second surface.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a diagrammatic sectional side view of an embodiment of an integrated circuit device according to various aspects of the present disclosure;

FIG. 2 is a diagrammatic top sectional view of a portion of the integrated circuit device of FIG. 1 according to various aspects of the present disclosure;

FIG. 3 is a diagrammatic sectional side view of another embodiment of an integrated circuit device according to various aspects of the present disclosure;

FIG. 4 s a diagrammatic top sectional view of a portion of the integrated circuit device of FIG. 3 according to various aspects of the present disclosure;

FIG. 5 is a flow chart of a method for fabricating an integrated circuit device according to aspects of the present disclosure; and

FIGS. 6-9 are various diagrammatic sectional side views of an embodiment of an integrated circuit device during various fabrication stages according to the method of FIG. 4.

### DETAILED DESCRIPTION

The present disclosure relates generally to integrated circuit device and methods for manufacturing integrated circuit devices. The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

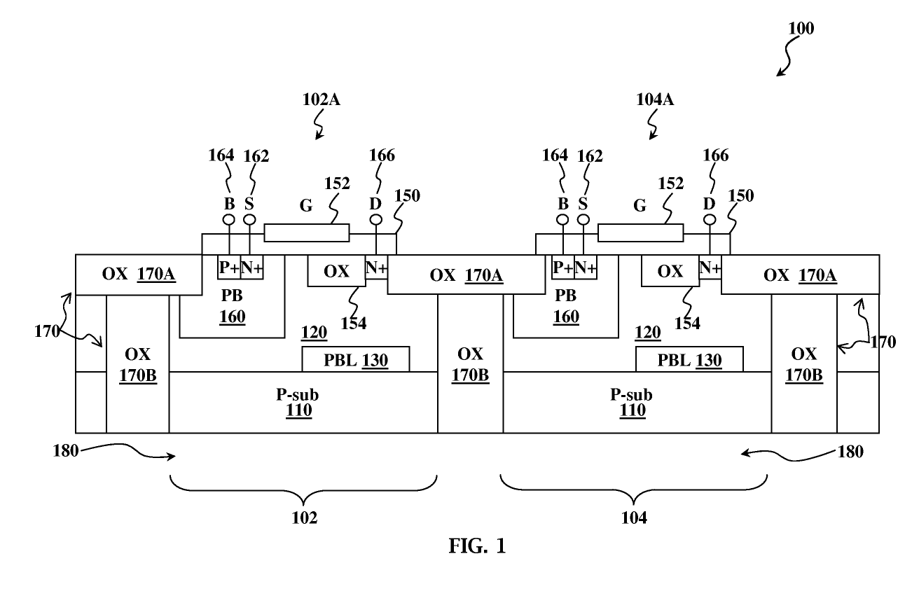

FIG. 1 is a diagrammatic sectional side view of an embodiment of an integrated circuit device 100, or portion thereof, according to various aspects of the present disclosure. The integrated circuit device 100 includes various active (or device) regions, such as active regions 102 and 104. The active region 102 includes a device 102A, and the active region 104 includes a device 104A. In the present embodiment, the devices 102A and 104A are a same type of device. The device 102A could alternatively be a different type of device than device 104A. In the present embodiment, the devices 102A and 104A are laterally double-diffused metal-oxide-semiconductor (LDMOS) devices. The LDMOS devices 102A and 104A are configured as n-channel LDMOS transistors, and thus, doping configurations described below are consistent with an n-channel LDMOS device. The LDMOS devices 102A and 104A can alternatively be configured as p-channel LDMOS transistors, in which case, the doping configurations described below would be consistent with a p-channel LDMOS device. In an embodiment, the LDMOS device 102A is configured as an n-channel LDMOS device, and the LDMOS device 104A is configured as a p-channel LDMOS device, or vice versa. The present disclosure is not limited by the illustration of the two LDMOS devices 102A and 104A and contemplates a single LDMOS device, multiple LDMOS devices, or combination of LDMOS devices and other devices (not shown).

The LDMOS devices 102A and 104A include a portion of a substrate 110. In the present embodiment, the substrate 110 is a p-type silicon substrate (P-sub) or wafer. Alternatively, the substrate 110 includes another elementary semiconductor material, such as germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Various features formed in and on the substrate 110 combine to form the LDMOS devices 102A and 104A in the active regions 102 and 104. For example, the substrate 110 includes various doped regions depending on design requirements as known in the art (e.g., p-type wells or n-type wells). In the present embodiment, the substrate 110 includes various doped regions in the device regions 102 and 104 that are configured to form the n-channel LDMOS devices 102A and 104a. The doped regions are doped with p-type dopants, such as boron or BF₂, and/or n-type dopants, such as phosphorus or arsenic. The doped regions may be formed directly on the substrate 110, in a P-well structure, in a N-well structure, in a dual-well structure, or using a raised structure. In the present embodiment, the substrate 110 includes an n-well region 120. The n-well region 120 is a deep n-well region that functions as a drift region (n-drift) for the LDMOS devices 102A and 104A. A p-buried layer (PBL) 130 is included in the n-well region 120 and can be positioned at an interface between the n-well region 120 and p-doped substrate 110. The PBL 130 underlies a drain (D) region of the LDMOS devices 102A and 104A.

The LDMOS devices 102A and 104A include a gate structure disposed over the substrate 110. In the present embodiment, the gate structure includes a gate dielectric 150, and a gate electrode 152 disposed on the gate dielectric 150. The gate structure could further include other features as known in the art, such as spacers. The gate dielectric 150 includes a silicon dioxide layer formed by thermal oxidation, chemical vapor deposition (CVD), physical vapor deposition (PVD), atomic layer deposition (ALD), other suitable processes, or combinations thereof. Alternatively, the gate dielectric 150 could include a high-k dielectric material, silicon oxynitride, silicon nitride, other suitable dielectric materials, or combinations thereof. Exemplary high-k dielectric materials include HfO₂, HfSiO, HfSiON, HfTaO, HfTiO, HfZrO, other suitable high-k dielectric materials, and/or combinations thereof. The gate dielectric 150 may have a multilayer structure, such as a layer of silicon oxide, and a high-k dielectric material layer formed on the silicon dioxide layer.

The gate electrode 152 is disposed overlying the gate dielectric 150. The gate electrode 152 is designed to be coupled to metal interconnects. In the present embodiment, the gate electrode 152 includes polycrystalline silicon (or polysilicon). The polysilicon can be doped for proper conductivity. Alternatively, the gate electrode 152 could include a metal, such as Al, Cu, W, Ti, Ta, TiN, TaN, NiSi, CoSi, other suitable conductive materials, or combinations thereof. The gate electrode 152 is formed by CVD, PVD, plating, or other proper processes. The gate electrode 152 may have a multilayer structure and may be formed in a multiple-step process.

A dielectric feature 154 is included in the LDMOS devices 102A and 104A. The dielectric feature 154 is formed near the drain (D) side of each device 102A and 104A. The dielectric feature 154 is an oxide (OX) feature, which can be utilized for releasing an electric field under the gate structures.

A p-type base (also referred to as p-body) region 160 is formed in the n-well region 120. The p-type base region 160 is formed near a source (S) side of each device 102A and 104A, and it may be laterally interposed between the gate structure (gate dielectric 150 and gate electrode 152) and an isolation structure 170 (which will be described in detail below). The p-type base region 160 includes a p-type dopant, such as boron. The p-type base 160 can be formed by an ion implantation process. In an example, an ion-implantation process with a tilt angle is used to form the p-type base region 160, such that the p-type base region 160 is extended partially underlying the gate structure, such as gate electrode 152. The tilt angle of the ion implantation can be tuned for optimized channel length.

The LDMOS devices 102A and 104A further include a source region 162, a body contact region 164 adjacent to the source region 162, and a drain region 166. The source region 162 and body contact region 164 are formed in the p-type base region 160, and the drain region 166 is formed in the n-well region 120, disposed between the dielectric feature 154 and isolation structure 170. In the present embodiment, the source region 162 and the drain region 166 are doped with n-type impurities (N+), such as phosphorous or arsenic, such that the LDMOS devices 102A and 104A are configured as n-channel LDMOS devices. The source and drain regions may have different structures, such as raised, recessed, or strained features. The body contact region 164 is doped with p-type impurities (P+), such as boron. The body contact region 164 may function as a guard ring in the LDMOS devices 102A and 104A.

Conventional techniques for isolating LDMOS devices from one another include junction isolation and silicon-on-insulator (SOI) isolation. The junction isolation technique uses doped wells (for example, a p-well to isolate n-channel LDMOS devices) or oxide features that extend along the sides of the LDMOS devices and only partially through the semiconductor substrate, for example partially through the substrate to a buried layer such as an n-buried layer. It has been observed that the partial extension of the doped wells/oxide features provides poor isolation because carriers are still able to laterally move through a bottom portion of the substrate from device to device. This causes latch-up issues, particularly in high-voltage technology devices. The SOI isolation technique similarly uses oxide features that extend along the sides of the LDMOS devices and only partially through the semiconductor substrate, for example partially through the substrate to a buried oxide layer disposed within the substrate. It has been observed that the SOI technique provides sufficient isolation, however, this technique suffers from self-heating and low breakdown voltages due to the buried oxide layer. Further, the SOI technique is expensive.

In the present embodiment, isolation structures 170 define and electrically isolate the various device (or active) regions of the integrated circuit device 100, such as device regions 102 and 104. In particular, isolation structures 170 isolate LDMOS device 102A from LDMOS device 104A, and further isolate LDMOS devices 102A and 104A from other neighboring devices (not shown). The devices 102A and 104A are disposed between isolation structures 170. The isolation structures 170 are dielectric isolation features, such as oxide (OX) isolation features. The isolation structures 170 can include shallow trench isolation (STI), field oxide (FOX), deep trench isolation (DTI), or local oxidation of silicon (LOCOS) features, or combinations thereof.

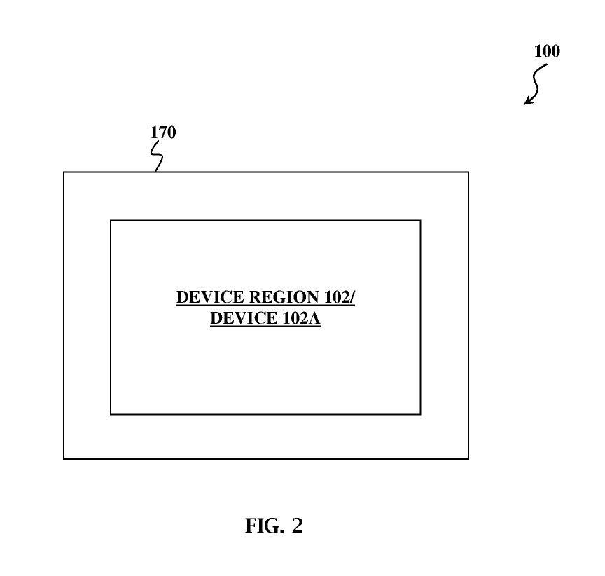

In the present embodiment, the isolation structures 170 include two portions 170A and 170B. The portion 170B extends laterally along the active regions 102 and 104 of the integrated circuit device 100. The isolation structures 170 thus extend through the entire substrate 110 (in other words, from a top surface to a bottom surface of the substrate 110), such that the devices 102A and 104A are completely isolated from one another by the isolation structures 170. For example, FIG. 2 is a diagrammatic top sectional view of a portion, specifically device region 102/LDMOS device 102A, of the integrated circuit device 100 of FIG. 1. As shown, the isolation structure 170 surrounds the device region 102 and LDMOS device 102A. Regardless where the diagrammatic top sectional view is taken, the isolation structure 170 surrounds the device region 102 and LDMOS device 102A, such that it is completely isolated from other devices, such as LDMOS device 104A. A diagrammatic top sectional view of device region 104 and LDMOS device 104A will similarly illustrate the device region 104 and LDMOS device 104A surrounded by the isolation structure 170.

Referring again to the diagrammatic sectional side view of the integrated circuit device 100 provided in FIG. 1, air exists along the bottom of each LDMOS device 102A and 104A. This can be referred to as an air barrier 180, which exists along the bottom surface of the substrate 110 of LDMOS devices 102A and 104A. Thus, LDMOS device 102A is isolated from other devices by the isolation structure 170 along the lateral sides of the LDMOS device 102A and the air barrier 180 along the bottom of the LDMOS device 102A. And LDMOS device 104A is similarly isolated with the isolation structure 170 along the lateral sides of the LDMOS device 104A and the air barrier 180 along the bottom of the LDMOS device 104A.

The isolation structure 170 and air barrier 180 provide excellent isolation for the LDMOS devices 102A and 104A. It has been observed that the disclosed integrated circuit device 100 provides improved heat dissipation and increased breakdown voltages. In some instances, this can be attributed to the air barrier 180. Further, since the isolation structure 170 extends through the entire substrate 110, completely isolating the LDMOS devices 102A and 104A from one another and other neighboring devices (not shown), the integrated circuit device 100 can prevent carriers from traveling laterally through a bottom portion of the substrate 110 from one device to another device. Different embodiments may have different advantages, and no particular advantage is necessarily required of any embodiment.

The integrated circuit device 100 is not limited to the aspects of the integrated circuit device described above. More specifically, the integrated circuit device could include memory cells and/or logic circuits. The integrated circuit device 100 could include passive components, such as resistors, capacitors, inductors, and/or fuses; and active components, such as metal-oxide-semiconductor field effect transistors (MOSFETs), complementary metal-oxide-semiconductor transistors (CMOSs), high voltage transistors, and/or high frequency transistors; other suitable components; and/or combinations thereof.

Further, additional features can be added in the integrated circuit device 100, and some of the features described above can be replaced or eliminated, for additional embodiments of the integrated circuit device 100. For example, the integrated circuit device 100 can include various contacts and metal features formed on the substrate 110. For example, silicide features may be formed by a silicidation process, such as a self-aligned silicide (salicide) process, which can include forming a metal material over a Si structure, subjecting the integrated circuit device to a raised temperature to anneal and cause reaction between the underlying silicon and metal to form silicide, and etching un-reacted metal away. The salicide material may be self-aligned to be formed on various features such as the source region, drain region and/or gate electrode to reduce contact resistance. A plurality of patterned dielectric layers and conductive layers can also be formed on the substrate 110 to form multilayer interconnects configured to couple the various p-type and n-type doped regions, such as the source region 162, body contact region 164, drain region 166, and gate electrode 152. In an embodiment, an interlayer dielectric (ILD) and a multilayer interconnect (MLI) structure are formed over the substrate 110, in a configuration such that the ILD separates and isolates the layers of the MLI structure. In furtherance of the example, the MLI structure includes contacts, vias and metal lines formed on the substrate. The MLI structure may be an aluminum interconnect structure, which includes materials such as aluminum, aluminum/silicon/copper alloy, titanium, titanium nitride, tungsten, polysilicon, metal silicide, or combinations thereof. Alternatively, the MLI structure may be a copper interconnect structure, which includes materials such as copper, copper alloy, titanium, titanium nitride, tantalum, tantalum nitride, tungsten, polysilicon, metal silicide, or combinations thereof.

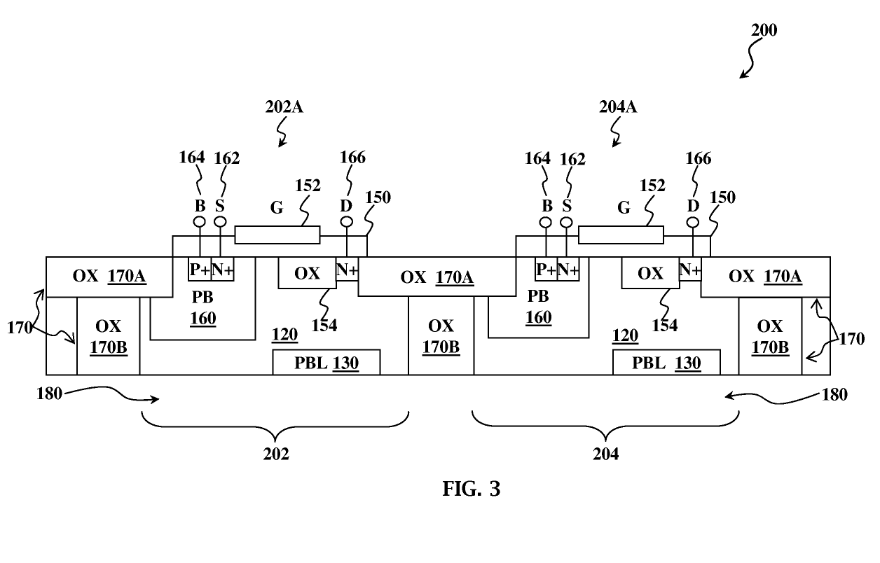

FIG. 3 is a diagrammatic sectional side view of an integrated circuit device 200 that is an alternative embodiment of the integrated circuit 100 of FIG. 1. The embodiment of FIG. 3 is similar in many respects to the embodiment of FIG. 1. Accordingly, similar features in FIGS. 1 and 3 are identified by the same reference numerals for the sake of clarity and simplicity. The integrated circuit device 200 has a device (or active) region 202 that includes a device 202A and a device (or active) region 204 that includes a device 204A. Devices 202A and 204A are LDMOS devices that are similar to LDMOS devices 102A and 104A. The isolation structures 170 similarly extend laterally along the device regions 202 and 204, isolating LDMOS device 202A from LDMOS device 204A, and from other devices (not shown). In the present embodiment, a bottom surface of the substrate 110 has been polished, such that all that remains of the substrate 110 is the n-well region 120. Accordingly, the isolation structures 170 extend through the substrate 110 to a bottom surface of the n-well region 120. Because the isolation structures 170 extend through the entire substrate 110, carriers can be prevented from traveling laterally through a bottom portion of the substrate 110 from device to device. Instead, carriers are contained within the isolation structures 170 and the air barrier 180 along the bottom of the LDMOS devices 202A and 204A.

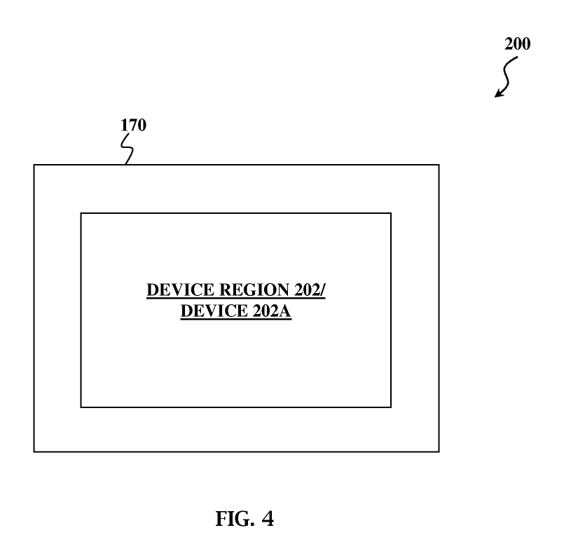

FIG. 4 is a diagrammatic top sectional view of a portion, specifically device region 202 and LDMOS device 202A, of the integrated circuit device 200 of FIG. 3. The isolation structure 170 surrounds the device region 202 and LDMOS device 202A. Similar to the integrated circuit device 100, regardless where the diagrammatic top sectional view is taken of integrated circuit device 200, the isolation structure 170 surrounds the device region 202 and LDMOS device 202A, such that it is completely isolated from other devices, such as LDMOS device 204A. A diagrammatic top sectional view of device region 204 and LDMOS device 204A will similarly illustrate the device region 204 and LDMOS device 204A surrounded by the isolation structure 170.

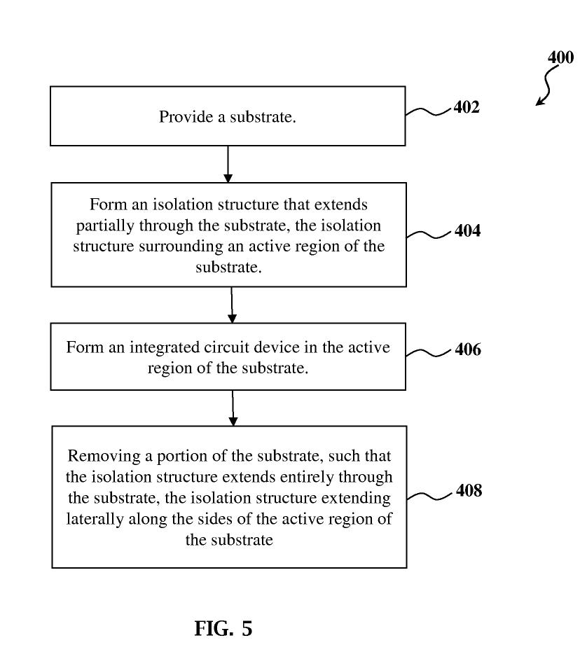

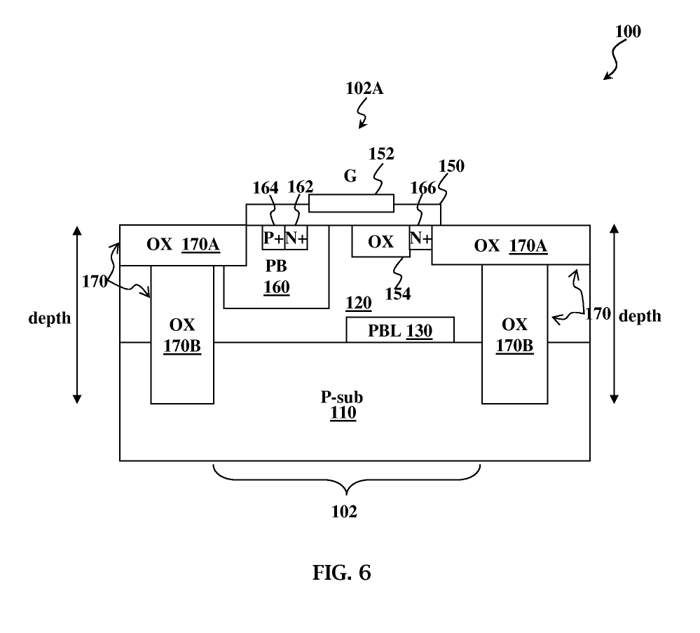

FIG. 5 is a flow chart of a method 400 for fabricating an integrated circuit device, such as the integrated circuit devices 100 and 200, according to aspects of the present disclosure. FIGS. 6-9 are diagrammatic sectional side views of a portion of the integrated circuit device 100, specifically device (or active) region 102, during various successive stages of manufacture according to the method 400 of FIG. 5.

Referring to FIGS. 5 and 6, the method 400 provides a substrate at block 402; forms an isolation structure that extends partially through the substrate at block 404, such that the isolation structure surrounds an active region of the substrate; and forms an integrated circuit device in the active region of the substrate at block 406. In the present embodiment, the substrate 110 is provided, the isolation structure 170 is formed extending partially through the substrate 110 and surrounding the active region 102 of the substrate, and the LDMOS device 102A is formed in the active region 102 of the substrate 110.

More specifically, referring to FIG. 6, the silicon p-type semiconductor substrate 110 is provided. An isolation structure 170 is formed in the substrate 110 surrounding the active region 102 of the substrate 110. In the present embodiment, the isolation structure 170 extends partially through the substrate 110, more particularly, from a top surface of the substrate 110 to a distance above a bottom surface of the substrate 110. A depth of the isolation structure 170 depends on device application voltage of the device formed in the active region 102. For example, in 60 V device technology, the depth of the isolation structure 170 can be from about 5 μm to about 10 μm.

The isolation structure 170 is formed by any suitable process. For example, formation of the isolation structure 170 may include dry etching a trench in the substrate 110 and filling the trench with insulator materials, such as silicon oxide, silicon nitride, or silicon oxynitride. The filled trench may have a multi-layer structure, such as a thermal oxide liner layer filled with silicon nitride or silicon oxide. In furtherance of the embodiment, the isolation structures 170 may be created using a processing sequence such as: growing a pad oxide, forming a low pressure chemical vapor deposition (LPCVD) nitride layer, patterning an isolation structure opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon

The LDMOS device 102A is formed within the device region 102 of the substrate 110, disposed between the isolation structures 170. In the present embodiment, the various features of the LDMOS device 102A are configured for an n-channel LDMOS device. Various processes are used to form the LDMOS device 102A. For example, the various doped regions can be formed by ion implantation processes, diffusion processes, annealing processes (e.g., rapid thermal annealing and/or laser annealing processes), and/or other suitable processes. Other processes including deposition processes, patterning processes, etching processes, and/or combinations thereof can be used to form the various features of the LDMOS device 102A. The deposition processes can include chemical vapor deposition (CVD), physical vapor deposition (PVD), atomic layer deposition (ALD), sputtering, plating, other suitable methods, and/or combinations thereof. The patterning processes can include photoresist coating (e.g., spin-on coating), soft baking, mask aligning, exposure, post-exposure baking, developing the photoresist, rinsing, drying (e.g., hard baking), other suitable processes, and/or combinations thereof. The photolithography exposing process may also be implemented or replaced by other proper methods such as maskless photolithography, electron-beam writing, ion-beam writing, and/or molecular imprint. The etching processes may include dry etching, wet etching, and/or other etching methods (e.g., reactive ion etching).

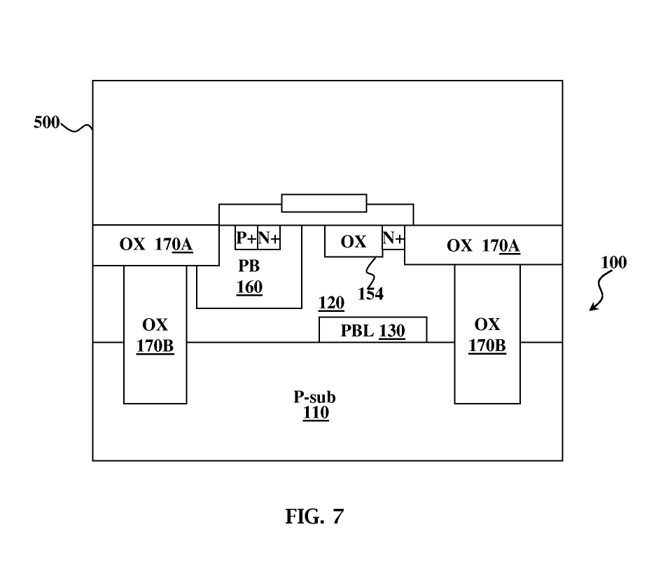

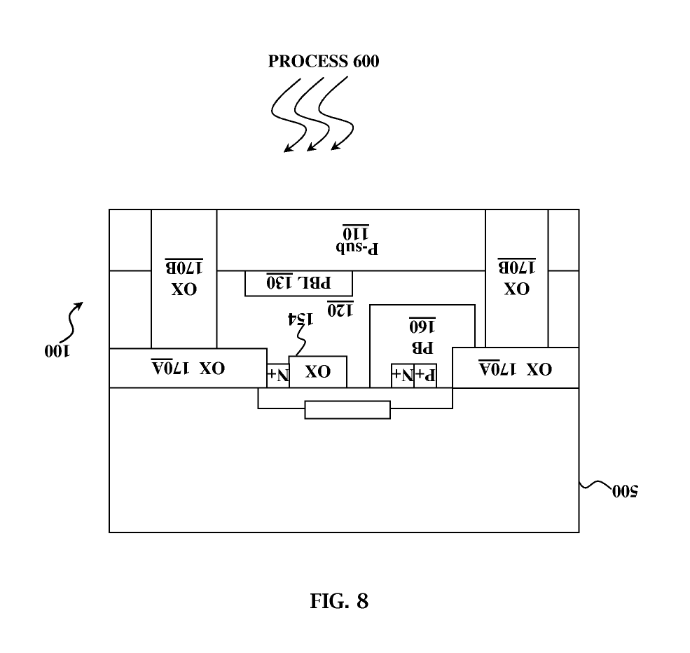

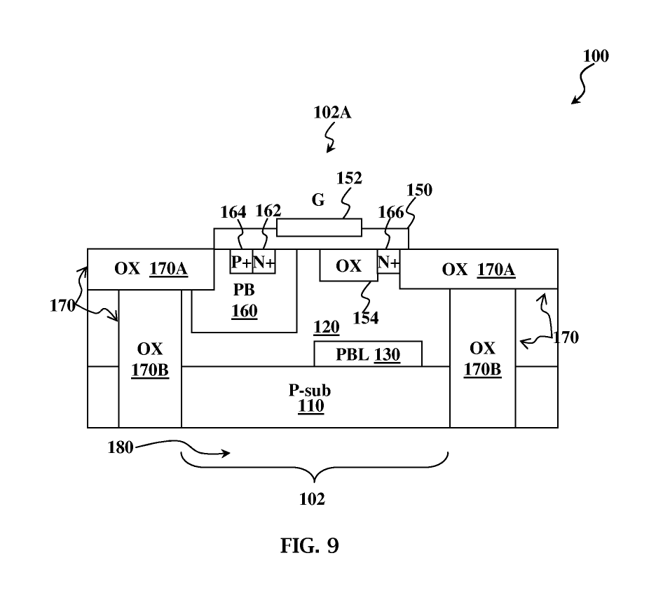

Referring to FIGS. 5 and 7-9, the method at block 408 removes a portion of the substrate, such that the isolation structure extends entirely through the substrate, such that the isolation structure extends laterally along the sides of the active region of the substrate. For example, referring to FIG. 7, a carrier wafer 500 is attached or bonded to a surface of the substrate 110. One or more layers (not shown) can be formed over the substrate 110 to effect coupling of the carrier wafer 500 to the substrate 110. As noted above, a multilayer interconnection structure may be formed over the substrate 110, and thus, the carrier wafer 500 may be bonded to the multilayer interconnection structure. Referring to FIG. 8, the bottom surface of the substrate 110 is then subjected to a process 600 to remove portions of the substrate 110, reducing the thickness of the substrate 110. In the present embodiment, the process 600 is a polishing process that is performed until the isolation structure 170 is exposed. The polishing process may be a chemical mechanical polishing (CMP) process. Referring to FIG. 9, after the thickness of the substrate is reduced, the isolation structure 170 extends through the entire substrate 110, from the top surface to the bottom surface. The isolation structure further extends along the sides of the active region 102 of the substrate 110, such that the LDMOS device 102A is completely isolated by the isolation structure 170 and air barrier 180.

Subsequent processing may form various contacts/vias/lines and multilayer interconnect features (e.g., metal layers and interlayer dielectrics) over the substrate 110, configured to connect the various features or structures of the LDMOS device 102A. The additional features may provide electrical interconnection to the device. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus comprising:
a substrate having a first surface and a second surface, the second surface being opposite the first surface;
a first device and a second device overlying the substrate; and
an isolation structure that extends through the substrate from the first surface to the second surface and between the first device and the second device.

2. The apparatus of claim 1 further comprising an air barrier along the second surface of the substrate, such that the first device is completely isolated from the second device by the isolation structure and air barrier.

3. The apparatus of claim 1 wherein the first device and the second device comprise a semiconductor device.

4. The apparatus of claim 3 wherein the semiconductor device comprises a lateral double-diffused metal-oxide-semiconductor (LDMOS) device.

5. The apparatus of claim 1 wherein the isolation structure comprises a shallow trench isolation (STI) feature, a deep trench isolation (DTI) feature, or a field oxide (FOX) feature.

6. The apparatus of claim 1 wherein the isolation structure comprises a dielectric material.

7. The apparatus of claim 6 wherein the dielectric material comprises an oxide material.

8. An integrated circuit device comprising:
a semiconductor substrate having a first surface and a second surface, the second surface being opposite the first surface;
a device that includes a source and drain region having a first type of conductivity disposed in the substrate, a gate structure disposed over the first surface of the substrate and between the source and drain region, and a body contact region having a second type of conductivity disposed in the substrate and adjacent to the source region, the second type of conductivity being different than the first type of conductivity; and
an isolation structure disposed in the semiconductor substrate between the device and a neighboring device, the isolation structure extending through the substrate from the first surface to the second surface.

9. The integrated circuit device of claim 8 wherein the isolation structure comprises a shallow trench isolation (STI) feature, a deep trench isolation (DTI) feature, or a field oxide (FOX) feature.

10. The integrated circuit device of claim 8 further comprising an air barrier along the second surface of the substrate, such that the device is completely isolated from the neighboring device by the isolation structure and air barrier.

11. The integrated circuit device of claim 8 further comprising:
a first doped region in the semiconductor substrate, the first doped region having the first type of conductivity, wherein the source, drain, and body contact regions are disposed in the first doped region; and
a second doped region in the first doped region such that the source and body contact regions are surrounded by the second doped region, the second doped region having the second type of conductivity.

12. The integrated circuit device of claim 11 wherein the first doped region comprises a drift region.

13. The integrated circuit device of claim 8 further comprising a multilayer interconnect (MLI) structure disposed over the first surface of the substrate.

14. A method comprising:
providing a substrate having a first surface and a second surface, the first surface being opposite the second surface;
forming an isolation structure that extends partially through the substrate from the first surface, the isolation structure surrounding an active region of the substrate;
forming an integrated circuit device in the active region of the substrate;
bonding a carrier wafer to the first surface of the substrate; and
polishing the second surface of the substrate until the isolation structure is reached, such that the isolation structure extends entirely through the substrate from the first surface to the second surface.

15. The method of claim 14 wherein the bonding the carrier wafer to the first surface of the substrate comprises bonding the carrier wafer to an interconnection structure disposed on the first surface of the substrate.

16. The method of claim 14 wherein the forming the isolation structure comprises forming a shallow trench isolation (STI), deep trench isolation (DTI), or field oxide (FOX) feature.

17. The method of claim 14 wherein the forming the isolation structure comprises:
etching a trench in the substrate that extends laterally along the sides of the active region of the substrate; and
filling the trench with a dielectric material.

18. The method of claim 17 wherein the filling the trench with a dielectric material comprises filling the trench with an oxide material.

19. The method of claim 14 wherein the forming the integrated circuit device comprises forming a lateral double-diffused metal-oxide-semiconductor (LDMOS) device.

20. The method of claim 14 further comprising providing an air barrier along the polished second surface of the substrate.
